(19) United States
(12) Patent Application Publication
(10) Pub. No.: US 2026/0153577 A1
(43) Pub. Date: Jun. 4, 2026

(54) PROBE HEAD FOR DNP-NMR SPECTROMETER WITH INTEGRATED MIRROR IN THE TEMPERATURE CONTROL GAS LINE FOR SAMPLE ILLUMINATION

(71) Applicant: Bruker BioSpin GmbH & Co. KG, Ettlingen (DE)

(72) Inventors: Christian REITER, Pfinztal (DE); Philipp ADERS, Karlsruhe (DE)

(21) Appl. No.: 19/405,932

(22) Filed: Dec. 2, 2025

(30) Foreign Application Priority Data
Dec. 4, 2024 (DE) 102024211608.4

(51) Int. Cl. G01R 33/31; G01R 33/46

(52) U.S. Cl. CPC G01R 33/31; G01R 33/4608

(57) ABSTRACT

An NMR-DNP probe head comprises a probe holder for receiving a sample vessel containing a sample substance surrounded by an RF coil, a temperature control device for maintaining the temperature of the sample substance, a microwave guide for supplying microwave radiation into the sample volume, and an illumination device comprising an optical fiber for photoinduced electron excitation of the sample substance in the sample volume. The temperature control device comprises a VT channel through which temperature control fluid can be supplied to the sample vessel during NMR measurement to maintain the temperature of the sample substance, the sample-side end of the optical fiber is arranged in the VT channel, and a deflecting mirror is arranged in the VT channel between the sample-side end of the optical fiber and the sample vessel that directs light exiting the optical fiber onto the sample substance in the sample volume of the sample vessel.

### BACKGROUND OF THE INVENTION

### Field of the Invention

The invention relates to an NMR probe head, configured for use in dynamic nuclear polarization, comprising a sample holder for receiving an elongated sample vessel with a sample substance in a sample volume, surrounded by an RF coil during NMR measuring mode, a temperature control device for temperature control of the sample substance in the sample vessel during NMR measuring mode, a microwave guide for supplying microwave radiation into the sample volume, as well as an illumination apparatus having a light guide for photoinduced electron excitation of the sample substance in the sample volume. An NMR probe head with these features is known from patent document EP 2 972 441 B1.

### Description of the Related Art

The present invention relates generally to the field of magnetic resonance. Nuclear magnetic resonance spectroscopy (NMR) is a commercially widespread, very powerful method of instrumental analysis for characterizing the chemical composition of substances or for determining the structure of substances in samples. In so doing, high-frequency pulses are irradiated into a test sample that is located in a strong, static magnetic field, which causes the alignment of nuclear spins in the sample substance, and the electromagnetic response of the test sample is measured. The information is then obtained integrally over a certain area of the sample, the so-called active volume, and evaluated to determine the chemical composition. The sample substance is typically placed in a substantially cylindrical sample tube in solid or liquid form. For measurement, it is placed in the measuring range of an NMR probe head of an NMR apparatus. There, the sample substance is exposed to a strong, homogeneous static magnetic field in a z-direction with flux density B₀, which leads to the alignment of nuclear spins in the sample substance. High-frequency electromagnetic pulses are then injected into the sample. This in turn generates high-frequency electromagnetic fields which are detected in the NMR apparatus. Information about the properties of the sample can be obtained from the detected RF fields. In particular, the chemical composition and chemical bonding in the sample can be inferred from the position and intensity of NMR lines.

In the field of nuclear magnetic resonance spectroscopy, there are various experimental methods that allow the nuclear polarization to be significantly increased, and therefore the detection sensitivity of the experiment. One of these methods is dynamic nuclear polarization (DNP). This technique requires the simultaneous irradiation of a magnetic microwave field at a frequency that is considerably higher (usually by a factor of 660) than the nuclear Larmor frequency of the protons. In dynamic nuclear polarization, polarization mediators, e.g. free radicals with unpaired electron spins, are present in the sample. Furthermore, it is exploited that electrons at low temperatures achieve a high polarization in a strong magnetic field. By irradiating with a microwave field at a suitable frequency, interactions cause a transfer of electron polarization to the atomic nuclei of the sample.

For liquid samples, so-called dissolution DNP is used. Here, the hyperpolarization of the test sample is carried out in a separate polarizer. Once the nuclear spins in the sample have reached a sufficiently high polarization, the sample can be quickly warmed to room temperature using a dissolution liquid, e.g. hot water. This process must occur quickly enough since the nuclear spins rapidly lose their polarization at higher temperatures.

Fast DNP is described, for example, in patent document U.S. Pat. No. 9,329,245 B2.

Patent document WO 2014/139573 A1 describes a method for generating free radicals for DNP and applications in NMR.

Patent document U.S. Pat. No. 9,739,862 B2 also discloses a DNP device in an NMR spectrometer.

Patent document U.S. Pat. No. 7,205,764 B1 discloses a so-called dissolution DNP arrangement for liquid NMR test samples comprising a sample head, a microwave guide for the test sample and light guides to excite the sample with short-wavelength light.

A DNP probe head for high-resolution liquid NMR is also described in patent document DE 10 2022 212 952 B4.

For certain experiments, it is advantageous to irradiate the samples with selected optical wavelengths, for example to optically excite a phase transition or to polarize the sample.

Patent document EP 3 608 684 B1 discloses a device for observing photoinduced processes in an NMR test sample. The device is arranged in a probe head of an NMR spectrometer and comprises a non-magnetic support structure with a cavity for receiving high-frequency coils and the test sample, as well as a light source that is arranged on the support structure, wherein the light source is configured so that it emits light into the test sample to trigger photoinduced processes. Additional microwave coupling is not described in DE 10 2022 212 952 B4. A disadvantage of this solution is the introduction of electrical components into the central magnetic field of an NMR probe head, which can influence the RF since the arrangement is changed due to dielectric and metallic materials near the coil.

Patent document WO 2021/250372 A1 describes an NMR probe head with an illumination apparatus and light guides as well as a diffuser. However, this is not a DNP probe head with additional microwave radiation. Furthermore, the described setup with irradiation along the axis of rotation would thus not be feasible with a MAS probe head.

In solid-state NMR spectroscopy, it is also known to reduce line broadening due to anisotropic interactions by having an NMR sample rotated at a high frequency (typically a few kHz) during spectroscopic measurement at the so-called “magic angle” of arctan√2 ≈54.74° relative to the static magnetic field (“MAS”=magic angle spinning). For this purpose, the sample is filled into a MAS rotor. MAS rotors are typically cylindrical tubes open at one end that are closed with a cap, wherein the cap is equipped with wing elements. The MAS rotor is arranged in a MAS stator, and the MAS rotor is driven via the blade elements for rotation by gas pressure. The totality of the MAS rotor and MAS stator is called a MAS turbine.

This is explained, for example, in patent document U.S. Pat. No. 10,459,044 B2 in which specifically an improved temperature control of an NMR-MAS rotor is described.

A microwave coupler for optimizing an NMR probe head for applications in MAS-DNP is described in patent document U.S. Pat. No. 10,120,044 B2.

A MAS stator of an NMR probe head suitable for DNP with optimized microwave irradiation is described in U.S. Pat. No. 10,197,653 B2 (=reference [11]).

Patent document U.S. Pat. No. 10,613,170 B2 describes an NMR-MAS probe head with an optimized MAS-DNP coil block for fast sample rotation.

However, references U.S. Pat. Nos. 10,459,044 B2, 10,120,044 B2, 10,197,653 B2 and 10,613,170 B2 do not mention sample illumination using light guides.

Finally, patent document EP 3 674 699 A1 discloses a process and a device for nuclear spin hyperpolarization by triplet-DNP.

The aforementioned EP 2 972 441 B1 describes a DNP-MAS spectrometer with an NMR probe head that includes a microwave guide to the test sample as well as a light guide to excite the sample with short-wave light without, however, addressing a specific technical implementation. In particular, this reference gives no indication of how a light guide could be effectively arranged so that the width of the light beam can be adjusted.

None of the previously known arrangements from the prior art disclose a concrete solution for implementing optical waveguides for a wavelength range smaller than 600 nm in a DNP MAS probe head. While MAS heads allow the fibers of a light guide to be attached to the coil holder, for DNP-MAS probe heads, the area at which the optical fiber could be attached must remain free for the introduction of microwave radiation.

In some cases, optical fibers were inserted into the MAS probe head and routed in an arc around the MAS stator. The fibers were then aligned from the side opposite the coil holder, via a hole introduced into the stator, onto the MAS rotor containing the test sample. The problem with this solution, however, is that the minimum bending radius is unsuitable for optical fibers that are for transferring light with a wavelength smaller than 600 nm, but for some applications, the near-UV wavelength range is required.

The light beam could also be directed onto the MAS rotor via the microwave waveguide, for example using mirrors. The disadvantage in this case is that the probe heads in the UHF range are spatially very long, and aligning and focusing the light beam over long distances would be very complex. Furthermore, this method also disrupts microwave radiation.

So far, no viable solution has been offered for how to integrate a light guide into the DNP probe head in such a way that the microwaves are not affected, but also that the light guide has to be bent as little as possible.

### SUMMARY OF THE INVENTION

The present invention involves providing a probe head for DNP measurements using conventional components of NMR sample holders (in particular MAS stators) as are common for an NMR-DNP apparatus with the above defined features, with which additional light excitation with adjustable beam width is possible. In particular, a space-saving solution is presented for illuminating an NMR test sample within the probe head without negatively affecting the magnetic field or the RF. Furthermore, excitation in the (near) UV range is made possible, wherein appropriate optical fibers are used that should be integrated with the smallest possible bending radius into the probe head. Furthermore, the solution according to the invention are retrofittable to existing, commercially available systems.

This is achieved by the present invention in a surprisingly simple yet effective manner by a DNP NMR probe head with the generic features described above, in that the temperature control device of the NMR probe head comprises a VT channel through which, in the NMR measuring mode, temperature control fluid can be supplied to the sample vessel for temperature control of the sample substance, that the sample-side end of the light guide is arranged in the VT channel for optical excitation of the test sample, and that a deflecting mirror is arranged in the VT channel between the sample-side end of the light guide and the sample vessel, which directs light exiting the light guide onto the sample substance in the sample volume of the sample vessel in NMR measuring mode.

The basic idea of the present invention is to configure the arrangement for introducing light for the optical excitation of the NMR test sample by a light guide in such a way that, on the one hand, the light can be directed onto the sample with as little attenuation as possible, while on the other hand not impairing any other important systems of the NMR-DNP probe head, in particular the microwave feed.

The solution according to the invention is particularly advantageous for typical MAS applications.

A MAS-DVT (“direct variable temperature”) stator, as is also used in DNP probe heads, namely usually has a temperature control gas channel (“VT channel”) that directs the temperature control gas to the sample. It is therefore directly connected to the room in which the RF coil and the NMR sample are located. This channel has no major constrictions or nozzles that would block a beam of light.

This channel usually runs through a bearing bushing. A mirror can easily be mounted in this bearing bushing, which deflects light that comes from the direction of the vertical axis onto the sample.

Optical fibers, which lead into the retaining bushing (or bearing bushing in the case of MAS probe heads) and direct their light onto the mirror, can be inserted along a vertical axis of the NMR probe head (“Z-axis”) without significant bends. The mirror reflects the incident light—usually at an angle of about 90°—onto the NMR test sample. Since the optical fibers end in the retaining socket, they do not impede the gas flow. The mirror can be mounted in such a way that it does not impede the gas flow.

The mirror can be arranged so that the temperature control gas also flows around it, and it is actively cooled by the temperature control gas flowing past it, which additionally contributes to a higher power output.

Existing commercial NMR probe heads can also be retrofitted with the illumination option according to the invention with reasonably little effort.

The present invention therefore provides an NMR-DNP probe head that elegantly solves all the technical problems mentioned above. Precisely because of the present invention, previously unimagined possibilities are now opening up for solid-state NMR.

Preferably, the deflecting mirror and at least the sample-side end of the light guide are arranged in the VT channel in such a way that their temperature is controlled by the temperature control fluid, in particular temperature control gas, flowing past during the NMR measuring mode.

This allows not only the test sample but also the sample-facing part of the illumination apparatus to be cooled for photoinduced electron excitation without significant additional technical effort, and the power output of the light on the sample can therefore be increased.

In a particularly preferred embodiment of the NMR-DNP probe head according to the invention, the light guide at least partially arranged in the VT channel is surrounded by an elongated sleeve and is displaceable along the longitudinal axis of this sleeve relative to the deflecting mirror.

This arrangement makes it possible, for a given opening angle, to adjust the width of the light beam at the sample position by varying the distance between the mirror and the fiber end of the light guide. The adjustable holder of the light guide makes it easy to optimize the current illumination of the NMR test sample during the DNP experiment.

Typically, the light guide is glued to the sleeve and, together with the sleeve, is moved relative to the deflecting mirror in an opening of the bearing bushing.

In practice, embodiments of the NMR-DNP probe head according to the invention have proven effective in which the light guide comprises a monofiber with a cross-section of less than or equal to 0.5 mm or consists of this monofiber, wherein the monofiber is guided substantially in a straight line through the NMR probe head.

In principle, the position of the sample-facing part of the illumination apparatus can be reached with the light guide on a relatively straight path from the lower end of the NMR probe head, which makes the use of fibers for the near-UV range possible. There is a relatively large amount of flexibility with regard to the utilized fiber. Fiber bundles can also be integrated in this way. In any case, this makes it possible to implement optical conductors in a DNP probe head even for a wavelength range of less than 600 nm.

In a first, particularly simple class of embodiments of the NMR probe head according to the invention, the deflecting mirror is configured as a simple plane mirror.

The additional costs for the mirror are negligible here. In conjunction with the linear displacement of the light guide relative to the deflecting mirror described above, the cone diameter of the light beam can be adjusted.

An alternative class of advantageous embodiments of the invention is characterized in that the deflecting mirror for focusing the deflected light from the sample-side end of the light guide onto the sample substance in the sample volume of the sample vessel has an in particular concavely curved mirror surface.

This allows the specific light output on the sample to be increased and, in particular in conjunction with the linear displacement of the light guide relative to the deflecting mirror described above, to be adjusted and varied almost arbitrarily. Furthermore, the geometry of the illuminating light beam can be optimally adapted to the geometry of the test sample. The light beam exiting the light guide is typically conical, and this light cone can be reduced by approaching the deflecting mirror, thereby increasing the light intensity on the test sample. Conversely, the light intensity on the sample can be reduced by removing the optical fiber from the deflecting mirror.

Most preferred is also a class of embodiments of the NMR-DNP probe head according to the invention, which are characterized in that the probe holder is configured as a MAS stator and the sample vessel as a MAS rotor.

This means that all the technical advantages of MAS technology described above, in particular a reduction of line broadening due to anisotropic interactions, can also be achieved with the NMR-DNP probe head according to the invention. In particular with MAS NMR-DNP probe heads, it is geometrically difficult to bring the excitation light to the center of the sample vessel, i.e., the MAS rotor, because during measuring mode—unlike with liquid samples—it is tilted at the magic angle and is therefore not directly accessible. Furthermore, the microwave conductor blocks another access point to the sample. In addition to the gas channels for the bearing and drive of the MAS rotor, a third channel is also present in a MAS probe head, which is provided to direct a temperature-controlled gas flow onto the rotor. This VT channel has no significant nozzles or constrictions that would block a light beam.

In preferred further developments of this class of embodiments, the NMR-MAS DNP probe head according to the invention is configured for NMR spectrometers with a magnetic field in the range of 400 MHz to 900 MHz.

Further developments are also advantageous in which the probe head is configured as a wide-bore probe head with an inner diameter greater than 6 cm.

For such probe heads, which have an inner diameter of more than 6 cm, it is significantly easier from a manufacturing perspective to equip the MAS DNP probe heads with an additional light guide than it is to equip probe heads having a smaller diameter.

Further developments of this class of embodiments are particularly advantageous which are characterized in that at least one bearing bushing, preferably two bearing bushings opposite each other on either side of the MAS stator, is/are arranged on the tilt axis of the MAS stator for tiltable attachment of the MAS stator in the sample head.

Such a bearing bushing rotatably bears the stator, guides temperature-controlled gas to the sample, and accommodates the light guide. This means that three functions can be implemented in a single component.

In practice, variants of these further developments have proven particularly effective in which the bearing bushings are part of the VT channel and have—preferably L-shaped—angled through bores (more precisely, two bores that meet each other at an angle) for conveying the temperature control fluid to the MAS rotor.

The deflecting mirror and the sample-side end of the light guide are integrated in an airtight manner into the bearing bushing. In so doing, the mirror and light guide tip are cooled by the flow of the temperature control gas in the VT channel, which promotes a particularly high power output.

The present invention also encompasses a bearing bushing for use in an NMR-MAS DNP probe head of the type described above, which is distinguished in that the deflecting mirror is attached, in particular firmly integrated, in the bending region of the L-shaped bore.

The two bearing bushings form the tilting axis of the MAS stator and are arranged centrally with respect to the MAS rotor. Therefore, at this point, the beam can be deflected directly onto the test sample by the deflecting mirror.

In advantageous embodiments of this bearing bushing configured according to the invention, a receptacle for an end section of the elongated sleeve surrounding the light guide and a hose connection for attaching a VT hose for supplying temperature control fluid are provided at an opening of the through bore (or of the two bores that meet each other at an angle).

These embodiments are in particular provided for applications in NMR-MAS-DNP probe heads according to the invention with an adjustable distance between the light guide and deflection mirror. The light beam can be easily adjusted to the current test sample by changing the distance.

In further advantageous embodiments, the bearing bushing according to the invention is made of an electrically non-conductive dielectric material.

This avoids disturbances to the electromagnetic field at the location of the NMR test sample.

Finally, the present invention also encompasses an NMR spectrometer with an NMR-DNP probe head and/or a bearing bushing according to the invention and of the type described above. The NMR spectrometer is distinguished in that a light source for generating light with a wavelength smaller than 600 nm is arranged outside the NMR probe head, and that light from this external light source can be coupled into the end of the light guide facing away from the sample.

An optical interface connects the setup to the external light guide. The latter can be inserted into the normally existing footbox of the NMR-DNP probe head. The section of the light guide up to the bearing bushing is arranged along a longitudinal axis of the probe head from the footbox to the bearing bushing.

Further advantages of the invention can be found in the description and the drawings. Likewise, according to the invention, the aforementioned features and those which are to be explained below can each be used individually or together in any desired combinations. The embodiments shown and described are not to be understood as an exhaustive list, but, rather, have an exemplary character for the description of the invention.

### BRIEF DESCRIPTION OF THE DRAWINGS

The invention is shown in the drawings and is explained in more detail using exemplary embodiments. In the drawings:

FIG. 1 shows a schematic representation of an embodiment of the NMR probe head according to the invention with a MAS stator in the vertical section as well as a MAS rotor with an NMR test sample and RF coils surrounding it in a spatial view;

FIG. 2a shows a schematic vertical section view of an embodiment of the bearing bushing according to the invention for rotatable suspension and gas supply of a MAS stator, with an integrated deflecting mirror and light guide tip with an optical fiber in a sleeve as well as with—indicated here in black—a conically expanded light beam corresponding to the numerical aperture of the fiber end;

FIG. 2b shows the bearing bushing of FIG. 2a rotated about its vertical axis with a VT channel for supplying temperature control gas (indicated by black arrows);

FIG. 3a shows a partially transparent spatial representation of the bearing bushing rotated about its vertical axis according to FIG. 2b;

FIG. 3b shows the bearing bushing of FIG. 3a in a non-transparent three-dimensional view; and

FIG. 4 shows a schematic longitudinal section view through an NMR spectrometer modified according to the invention with a spectrometer console, gyrotron, light source and temperature control device.

### DETAILED DESCRIPTION

The present invention relates to an NMR probe head 1 for receiving sample substance for carrying out NMR measurements in a homogeneous region of an NMR magnetic field, wherein the NMR probe head 1 is set up for use for dynamic nuclear polarization (“DNP”).

An associated NMR spectrometer is suitable either to optically excite molecules present in the test sample or to activate molecules in the test sample by photo-induced electron transfer, so that DNP and hyperpolarization are thereby also enabled. In particular, it will be used to perform DNP-MAS NMR spectroscopy.

An NMR test sample located in an NMR sample vessel, preferably in a MAS rotor, is to be irradiated with light of a specific wavelength during the measurement, for example to optically excite a phase transition or to polarize a test sample. Ideally, this should also be possible under DNP conditions (microwave radiation at a temperature of 100K).

Hyperpolarization of a magnetic resonance sample with a suitable device enables an increase in detection sensitivity compared to conventional NMR spectroscopy. Molecules capable of forming photoexcited states are combined with an NMR test sample. This test sample can be either in a frozen solution or as a solid sample in a homogeneous magnetic field. Optical radiation is used to generate photoexcited electronic states of molecules, and microwave radiation can be used simultaneously to stimulate electron spin transitions at one or more unpaired electron spins in the optically excited molecule and associated nuclear spin transitions, thereby generating a dynamic polarization of the nuclear spins in the magnetic resonance sample.

In particular, the device comprises a sample holder 2 for receiving an elongated sample vessel 4 with a sample substance in a sample volume surrounded by an RF coil 3 during NMR measuring mode, a temperature control device 47 for temperature control of the sample substance in the sample vessel 4 during the NMR measuring mode, a microwave guide 5 for supplying microwave radiation into the sample volume, as well as an illumination apparatus having a light guide 6 for photoinduced electron excitation of sample substance in the sample volume.

Compared to conventional NMR probe heads according to the prior art, the present invention is characterized in that the temperature control device 47 of the NMR probe head 1 comprises a VT channel 7 through which, in NMR measuring mode, temperature control fluid can be supplied to the sample vessel 4 for temperature control of the sample substance, that the sample-side end of the light guide 6 is arranged in the VT channel 7, and that a deflection mirror 8, which directs the light exiting the light guide 6 onto the sample substance in the sample volume of the sample vessel 4 in NMR measuring mode, is arranged in the VT channel 7 between the sample-side end of the light guide 6 and the sample vessel 4.

The deflecting mirror 8 and at least the sample-side end of the light guide 6 are arranged in the VT channel 7 such that their temperature is controlled by the temperature control fluid flowing past during the NMR measuring mode.

The light guide 6, which is at least partially arranged in the VT channel 7, is surrounded by an elongated sleeve 9 and is movable along the longitudinal axis of this sleeve 9 relative to the deflecting mirror 8 in order to adjust the distance between the light guide 6 and the deflecting mirror 8.

Preferably, the sample holder 2 is configured as a MAS stator and the sample vessel 4 as a MAS rotor.

In particularly preferred embodiments of the NMR-MAS probe head 1 according to the invention, two bearing bushings 10′; 10″ opposite each other on either side of the MAS stator, are arranged on the tilt axis of the MAS stator for tiltable attachment of the MAS stator in the sample head 1. One of the bearing bushings 10′; 10″ is part of the VT channel 7 and has preferably L-shaped angled through bores 11′; 11″ for conducting the temperature control fluid to the MAS rotor. The deflecting mirror 8 is firmly integrated in the bending area of the L-shaped bore 11′. At an opening 12′ in the through bore 11′, a receptacle for an end section of the elongated sleeve 9 surrounding the light guide 6 and a hose connection for attaching a VT hose 48 for supplying temperature control fluid are provided.

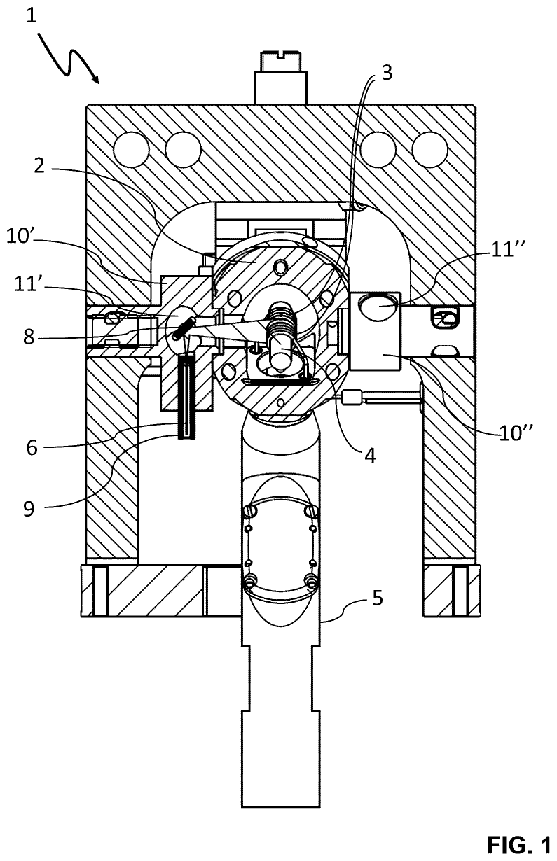

In FIG. 1, a cross-sectional view of an NMR-MAS probe head 1 according to the invention is depicted at the top. The MAS stator can be seen at a tilted angle, wherein the RF coil 3 is arranged in the center. The suspension of the MAS stator by means of the two bearing bushings 10′; 10″ is located on both sides of said stator. The bearing bushing 10′ depicted on the left in the top view comprises the VT channel 7 for sample temperature control as well as the sample-side end of the light guide 6, whose light coming from below is deflected by 90° into the NMR test sample in the sample vessel 4 via the deflecting mirror 8 attached in the bearing bushing 10′. Microwaves are also coupled in from below via a waveguide 5.

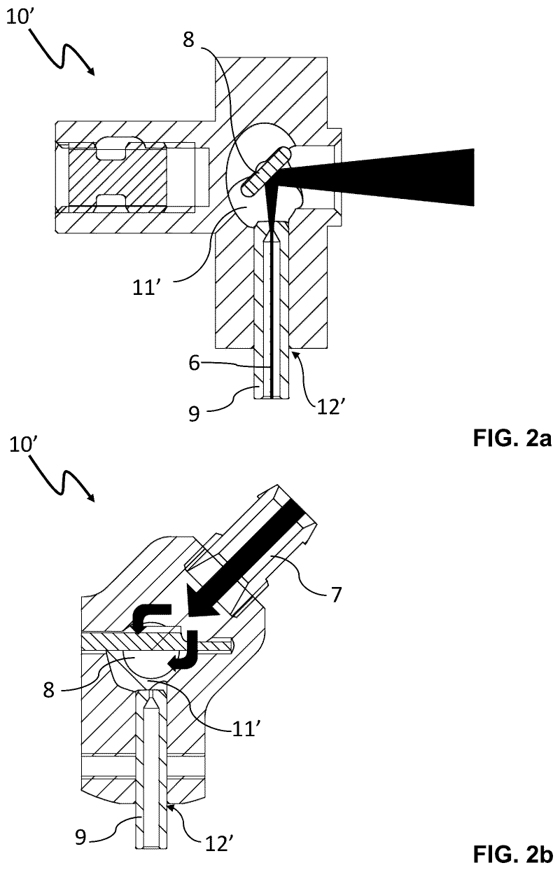

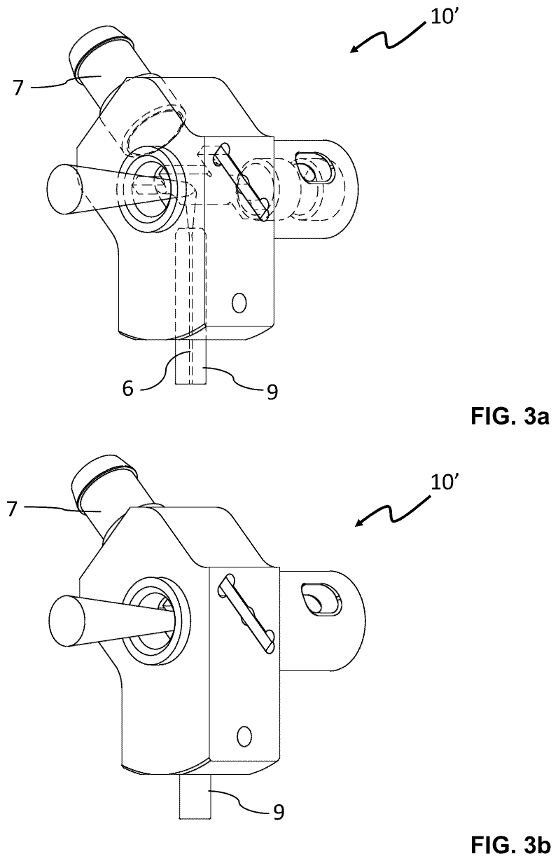

FIGS. 2a to 3b show, in different views, substantial aspects of a bearing bushing 10′ adapted according to the invention with the light guide 6 and the deflecting mirror 8 for the rotatable suspension of and gas supply to a MAS stator.

The bearing bushing 10′ is arranged centrally relative to the MAS stator, i.e. on the tilting axis of the MAS stator. The bearing is therefore located to the side of the center of the MAS stator, where the NMR test sample is located.

The bearing bushing 10′ also directs the VT (variable temperature) gas flow for controlling the temperature of the sample. The light guide 6 and deflecting mirror 8 can be installed directly in the bearing bushing 10′ so that the light beam is directed exactly in the center of the measuring sample or the MAS rotor. The bearing bushing 10′ is a separate component and can therefore be easily replaced at any time which enables the retrofitting of existing conventional NMR probe heads with the innovations of the present invention.

The optical fibers 6 are movable along their longitudinal axis, e.g. mounted parallel to the temperature control gas channel 7. The variable distance between the end of the optical fibers 6 and the deflecting mirror 8 also allows the light cone that hits the sample to be varied.

The adjustability of the light beam width is also advantageous in that it allows the option of placing a sample in the center of the MAS rotor and of narrowing the light beam to such an extent that a higher energy density at the sample position can be achieved. Alternatively, the light beam can be widened to illuminate the entire MAS rotor. Ideally, the position of the sleeve 9 is adjustable from the outside in order to adjust the setting directly during a measurement.

To stimulate phase transitions, light in the UV range is radiated in, i.e. with a wavelength smaller than 600 nm. The light guides 6 must be made of UV-resistant material.

The MAS rotor or the NMR sample tube must be optically transparent so that the light can reach the sample.

The deflecting mirror 8 can be a simple plane mirror. However, it can also be configured to be concave in order to better adapt the beam to the sample geometry.

Advantages that result from the mirror arrangement according to the invention:
When using a planar mirror arranged at less than 45°, the cone diameter of the light beam can be easily adjusted by adjusting the height of the light guide 6.
The mirror arrangement allows the use of a thin monofiber (diameter approximately 0.2 mm) which can be guided relatively straight (i.e., without significant bending) upwards in the NMR probe head 1, thereby preventing damage to the fiber and loss of power. There is also nothing fundamentally preventing the use of a fiber bundle.
The light guide 6 allows the use of an external light source and therefore higher light output.
The deflecting mirror 8 and the fiber end normally heat up during operation. The arrangement of the optics in the VT channel 7 ensures that the components are continuously cooled and also prevents contamination.
The deflecting mirror 8 or the bearing bushing 10′ can be replaced very easily.
Beam focusing can be further optimized using three-dimensional mirror geometries.

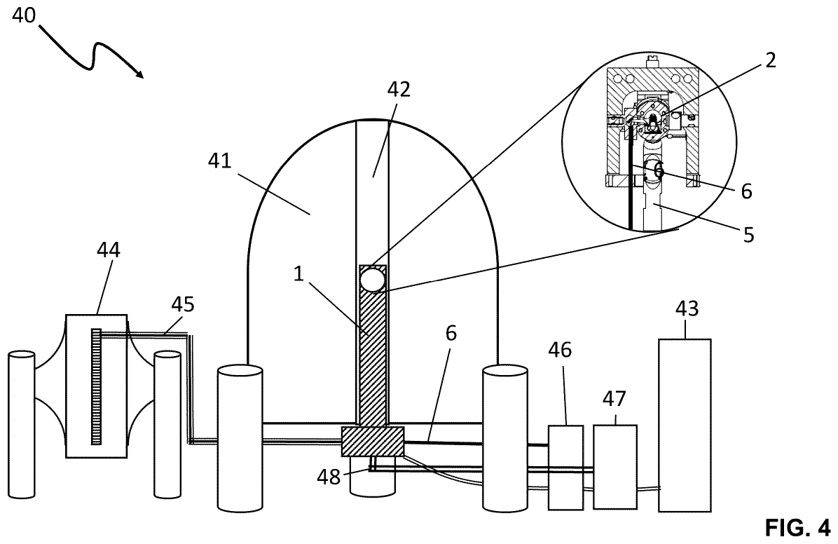

Finally FIG. 4 schematically shows an NMR spectrometer 40 equipped with an NMR probe head 1 according to the invention that includes a sample holder 2 configured as a MAS rotor with a modified bearing bushing 10′. It comprises an NMR magnet 41 with a magnetic bore 42, into which the NMR probe head 1 is inserted from below. Part of the NMR spectrometer 40 is a spectrometer console 43 for controlling the measurements and recording and, optionally, forwarding NMR measurement values. Other components of the arrangement are a gyrotron 44 for the generation of microwaves as well as a microwave transmission line 45 for the transfer of microwave energy into the microwave conductor 5. Also an external light source 46 arranged outside the NMR magnet 41 is available, by which light power is coupled into the light guide 6. A temperature control device 47 generates temperature control fluid, usually temperature control gas, which is then routed via a VT hose 48 into the VT channel 7.

### LIST OF REFERENCE SIGNS

1 NMR probe head
2 sample holder
3 RF coil
4 sample vessel
5 microwave conductor
6 light guide
7 VT channel
8 deflection mirror
9 sleeve
10′; 10″ bearing bushing
11′; 11″ bore
12′ opening
40 NMR spectrometer
41 NMR magnet
42 magnetic bore
43 spectrometer console
44 gyrotron
45 microwave transmission line
46 light source
47 temperature control device
48 VT hose

1. An NMR probe head, configured for use in dynamic nuclear polarization, comprising:
a sample holder for receiving an elongated sample vessel with a sample substance in a sample volume surrounded by an RF coil during NMR measuring mode,
a temperature control device for temperature control of the sample substance in the sample vessel during the NMR measuring mode, wherein the temperature control device of the NMR probe head comprises a VT channel through which, in NMR measuring mode, temperature control fluid can be supplied to the sample vessel for temperature control of the sample substance,
a microwave guide for supplying microwave radiation into the sample volume,
an illumination apparatus having a light guide for photoinduced electron excitation of sample substance in the sample volume, wherein a sample-side end of the light guide is arranged in the VT channel, and
a deflecting mirror arranged in the VT channel between the sample-side end of the light guide and the sample vessel, the deflecting mirror directing light exiting the light guide onto the sample substance in the sample volume of the sample vessel during NMR measuring mode.

2. The NMR probe head according to claim 1, wherein the deflecting mirror and at least the sample-side end of the light guide are arranged in the VT channel such that their temperature is controlled by the temperature control fluid flowing past during the NMR measuring mode.

3. The NMR probe head according to claim 1, wherein the light guide arranged at least partially in the VT channel is surrounded by an elongated sleeve and is movable along the longitudinal axis of this sleeve relative to the deflecting mirror.

4. The NMR probe head according to claim 1, wherein the light guide comprises a monofiber with a cross-section <0.5 mm, and wherein the monofiber is guided substantially in a straight line through the NMR probe head.

5. The NMR probe head according to claim 1, wherein the deflecting mirror is configured as a plane mirror.

6. The NMR probe head according to claim 1, wherein the deflecting mirror for focusing the deflected light from the sample-side end of the light guide onto the sample substance in the sample volume of the sample vessel has a concavely curved mirror surface.

7. The NMR probe head according to claim 1, wherein the sample holder is configured as a MAS stator and the sample vessel as a MAS rotor.

8. The NMR-MAS probe head according to claim 7, wherein the probe head is configured for NMR spectrometers with a magnetic field in the range of 400 MHz to 900 MHz.

9. The NMR-MAS probe head according to claim 7, wherein the probe head is configured as a wide-bore probe head with an inner diameter of at least 6 cm.

10. The NMR-MAS probe head according to claim 7, wherein at least one bearing bushing, preferably two bearing bushings opposite each other on either side of the MAS stator, is/are arranged on a tilt axis of the MAS stator for tiltable attachment of the MAS stator in the probe head.

11. The NMR-MAS probe head according to claim 10, wherein one of the bearing bushings is part of the VT channel and has at least one angled through bore for conducting the temperature control fluid to the MAS rotor.

12. A bearing bushing for use in an NMR-MAS probe head according to claim 11, wherein the bore is L-shaped, and wherein the deflecting mirror is located in the angled region of the bore.

13. The bearing bushing according to claim 12 wherein the light guide arranged at least partially in the VT channel is surrounded by an elongated sleeve and is movable along the longitudinal axis of this sleeve relative to the deflecting mirror and, at an opening of the through bore, a receptacle for an end section of the elongated sleeve surrounding the light guide and a hose connection for attaching a VT hose for supplying temperature control fluid are provided.

14. The bearing bushing according to claim 12, wherein the bearing bushing is made of an electrically non-conductive dielectric material.

15. An NMR spectrometer with a probe head according to claim 1, wherein a light source for generating light with a wavelength smaller than 600 nm is arranged outside the NMR probe head, and wherein light from this external light source can be coupled into an end of the light guide facing away from the probe.
